(19) United States
(12) Patent Application Publication
(10) Pub. No.: US 2017/0206132 A1
(43) Pub. Date: Jul. 20, 2017

(54) HYBRID STORAGE SYSTEM USING P2P AND DATA TRANSMISSION METHOD USING SAME

(71) Applicant: POSTECH ACADEMY-INDUSTRY FOUNDATION, Pohang-si (KR)

(72) Inventors: Hwang Jun SONG, Pohang-si (KR); Yun Min GO, Anseong-si (KR); Dong Hyeok HO, Seoul (KR); Gi Seok PARK, Seoul (KR)

(21) Appl. No.: 15/324,674

(22) PCT Filed: Feb. 4, 2015
(86) PCT No.: PCT/KR2015/001135

§ 371 Date: Jan. 6, 2017

(30) Foreign Application Priority Data
Jul. 8, 2014 (KR) 10-2014-0085103

(51) Int. Cl. G06F 11/10; H03M 13/15; G06F 3/06; H03M 13/37

(52) U.S. Cl. CPC G06F 11/1076; H03M 13/3761; H03M 13/154; G06F 3/0619; G06F 3/064; G06F 3/067

(57) ABSTRACT

The present invention relates to a hybrid storage system combining a cloud storage system and a P2P storage system. The hybrid storage system comprises: a node management unit for measuring bandwidths for a cloud storage system server and a P2P storage peer; a variable control unit for calculating a packet distribution vector for determining the unit of data to be dispersed in the sever and the peer and a fountain coding rate for determining encoding for data to be stored in the server and the peer; an encoding unit for fountain-encoding data to be stored in the server and the peer, according to the foundation coding rate; and a scheduler for calculating a transmission time which is the time required for data transmission to the server and the peer on the basis of the measured bandwidths and the packet distribution vector, and transmitting information on the transmission time to the variable control unit. Therefore, the present invention can solve a privacy problem of user data, improve a data recovery rate, and at the same time, store data while minimizing a transmission time.

### TECHNICAL FIELD

The present disclosure relates to a storage system, and more particularly to a hybrid storage system in which a cloud storage system and a Peer-to-Peer (P2P) storage system are combined.

### BACKGROUND ART

Currently, many remote storage services such as Amazon Glacier, Google Drive, Microsoft SkyDrive, etc., which can enable users to remotely access ubiquitous data in internet environments, are being successfully in service.

For example, the number of users of Dropbox which is one of the remote storage services reaches one hundred million. Generally, such the remote storage systems may be classified into cloud storage systems and Peer-to-Peer (P2P) storage systems.

The cloud storage system based on a server cluster can guarantee high data retrievability rate by using a mirroring technique in which stored data are duplicated. Here, the data retrievability may mean that stored data can be retrieved without any errors at whatever point a user wants. However, in the cloud storage system, all of data are stored in a server of the system, and thus there may be a concern that the stored data may be exposed to a third user or a manager. In this reason, data privacy is one of important problems which should be resolved in the cloud storage system. Also, an expandability problem of the cloud storage system according to the increased number of storage users is a critical problem.

On the other hand, such the problems of the cloud storage system can be resolved in the P2P storage system. In the P2P storage system, peers share their resources, and thus the increased number of users of the P2P storage system may induce increase of the amount of resources for the P2P storage system. Also, in the P2P storage system, a user can download stored data simultaneous from a plurality of peers so that the higher download speed can be achieved as compared to the cloud storage system. Furthermore, since the user data can be stored a plurality of peers in distributive manner, data privacy can also be remarkably enhanced. However, the biggest problem of the P2P cloud storage system is a low data retrievability rate due to such the dynamic properties of peer-to-peer mechanism. In this reason, there have been many studies to guarantee a retrievability rate identical to that of the cloud storage system. As an efficient method for enhancing data retrievability rate in the P2P storage system, a method in which an erasure protection code such as LDPC, LT code, or RS code is used for encoding data to be stored, and the encoded data are stored in a plurality of peers so as to satisfy required data retrievability rate. However, even such the method may cause increase of transmission time for storing the data, and thus cause another problem.

As described above, the cloud storage service and the P2P storage service may have individual merits and demerits. The cloud storage system is capable to use servers having low error rates thereby having higher data retrievability rate. However, it has the problem of data privacy due to a centralized storing of user data and the problem in service expandability due to rapid increase of users.

On the contrary, the P2P storage system has advantage in storage expandability as compared to the cloud storage system, and can guarantee higher data privacy than that of the cloud storage system by storing user data in the distributive manner. However, there may occur a problem of lower data retrievability rate due to dynamic characteristics of the peer-to-peer mechanism.

### DISCLOSURE

### Technical Problem

The purpose of the present invention for resolving the above-described problem is to provide a hybrid storage system combining and utilizing a cloud storage system and a Peer-to-Peer (P2P) storage system, in order to overcome limitation when the two storage systems are utilized independently.

Another purpose of the present invention for resolving the above-described problem is to provide a method of transmitting data by using a hybrid storage system.

### Technical Solution

In order to achieve the above-described purpose, a hybrid storage system may comprise a node management unit measuring bandwidths for a cloud storage server and a Peer-to-Peer (P2P) storage peer; a variable control unit calculating a packet distribution vector for determining data units to be distributed into the cloud storage server and the P2P storage peer, and a fountain coding rate for determining coding rates of data to be stored in the cloud storage server and the P2P storage peer; an encoding unit performing encoding on the data to be stored in the cloud storage server and the P2P storage peer based on the fountain coding rate; and a scheduler calculating a transmission time required to transmit data to the cloud storage server and the P2P storage peer based on the measured bandwidths and the packet distribution vector, and transferring information on the transmission time to the variable control unit.

Here, the packet distribution vector may represent a number of packets including encoded symbols distributed to the cloud storage server and a number of packets including encoded symbols distributed to the P2P storage peer.

Here, the variable control unit may re-calculate the packet distribution vector by using the measured bandwidths and the information on the transmission time.

Here, the variable control unit may determine the packet distribution vector so that data retrievability becomes not less than a predetermined threshold.

Also, the data retrievability may be calculated based on a decoding failure rate and a system reliability, the decoding failure rate may be calculated based on a number of source symbols and a number of encoded symbols required for decoding the source symbols, and the system reliability may be a probability of obtaining encoded symbols not less than the number of encoded symbols required for decoding the source symbols.

Here, the variable control unit may determine the packet distribution vector based on a storage space remaining in the peer and a number of encoded symbols included in a packet, so that encoded symbols less than a number of source symbols are stored in the server and the peer.

Here, the encoding unit may perform Luby Transform (LT) encoding.

Here, the scheduler transmits symbols encoded according to the fountain coding rate to the cloud storage server and the P2P peer based on the packet distribution vector.

In order to achieve the above-described another purpose, an aspect of the present invention provides a method of distributing data into a cloud storage server and a Peer-to-Peer (P2P) storage server by using a hybrid storage system, the method comprising: obtaining information on bandwidths for a cloud storage server and a Peer-to-Peer (P2P) storage peer; initializing a minimum number of packets, a maximum number of packets, and a number of packet-intervals in order to determine a packet distribution vector based on the information on the bandwidths; calculating a data retrievability rate and a transmission time required to transmit data to the cloud storage server and the P2P storage peer based on the information on the bandwidths; and determining the packet distribution vector so that the data retrievability rate and the transmission time satisfy predetermined thresholds.

Here, the method may further comprise transmitting data to the cloud storage server and the P2P storage peer in distributive manner according to the packet distribution vector.

Also, in the transmitting data to the cloud storage server and the P2P storage peer in distributive manner, the data may be transmitted as encoded according to a fountain coding rate determined based on the packet distribution vector.

Here, the data retrievability may be calculated based on a decoding failure rate and a system reliability, the decoding failure rate may be calculated based on a number of source symbols and a number of encoded symbols required for decoding the source symbols, and the system reliability may be a probability of obtaining encoded symbols not less than the number of encoded symbols required for decoding the source symbols.

Here, the determining the packet distribution vector may further comprise re-determining the packet distribution vector by reflecting information on changed bandwidths when the bandwidths are changed.

Here, in the determining the packet distribution vector, when the bandwidths for the cloud storage server and the P2P storage peer decrease, a peer may be added so that a bandwidth of the added peer is larger than a decreased amount of the bandwidths, and the packet distribution vector is re-determined according to the added peer.

In order to achieve the above-described another purpose, another aspect of the present invention provides an operation method performed by a hybrid storage system, comprising: measuring bandwidths for a cloud storage server and a Peer-to-Peer (P2P) storage peer; calculating a packet distribution vector for determining data units distributed into the cloud storage server and the P2P storage peer, and a fountain coding rate for determining encoding rates of data to be stored in the cloud storage server and the P2P storage peer; encoding the data to be stored in the cloud storage server and the P2P storage peer based on the fountain coding rate; and calculating a transmission time required to transmit data to the cloud storage server and the P2P storage peer based on the measured bandwidths and the packet distribution vector, and transferring information on the transmission time to the variable control unit.

### Advantageous Effects

The above-described hybrid storage system according to exemplary embodiments of the present disclosure can transmit data by determining a packet distribution vector so as to enhance data retrievability and minimize data transmission time.

Also, using the P2P storage system together with the cloud storage system, the data privacy system can be solved by the hybrid storage system.

### DESCRIPTION OF DRAWINGS

FIG. 1 is a block diagram to explain a hybrid storage system according to an exemplary embodiment of the present disclosure.

FIG. 2 is a conceptual diagram explaining determination of a packet distribution vector according to an exemplary embodiment of the present disclosure.

FIG. 3 is a flow chart explaining a data transmission method using a hybrid storage system according to an exemplary embodiment of the present disclosure.

### BEST MODE

While the invention is susceptible to various modifications and alternative forms, specific embodiments thereof are shown by way of examples in the drawings and will herein be described in detail. It should be understood, however, that there is no intent to limit the invention to the particular forms disclosed, but on the contrary, the invention is meant to cover all modifications, equivalents, and alternatives falling within the spirit and scope of the invention. Like numbers refer to like elements in the accompanying drawings.

It will be understood that, although the terms first, second, A, B, etc. may be used herein to describe various elements, these elements should not be limited by these terms. These terms are only used to distinguish one element from another. For example, a first element could be termed a second element, and, similarly, a second element could be termed a first element, without departing from the scope of the inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, it will be understood that when an element is referred to as being “directly connected” or “directly coupled” to another element, there are no intervening elements present.

The terminology used herein is for the purpose of describing particular embodiments only and is not intended to be limiting of the invention. As used herein, the singular forms “a”, “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present invention will be described in detail with reference to the appended drawings.

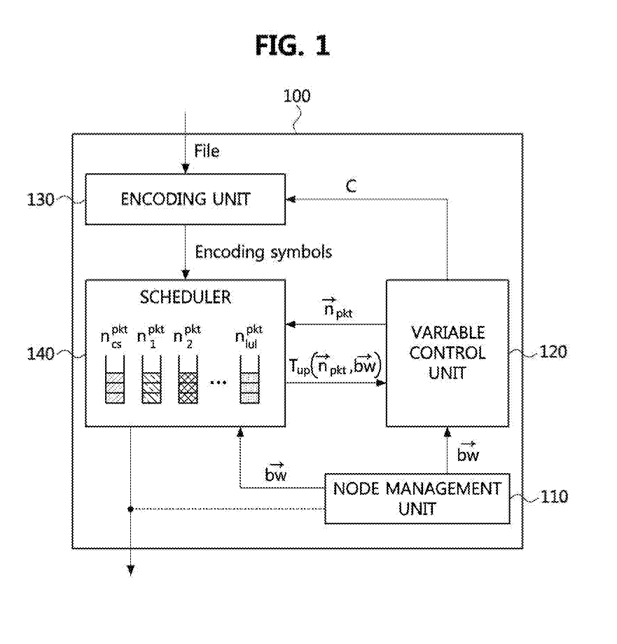

FIG. 1 is a block diagram to explain a hybrid storage system according to an exemplary embodiment of the present disclosure.

Referring to FIG. 1, a hybrid storage system 100 according to an exemplary embodiment of the present disclosure may comprise a node management unit 110, a variable control unit 120, an encoding unit 130, and a scheduler 140.

The node management unit 110 may measure bandwidths for a server of a cloud storage system and peers of a P2P storage system, and transmit information on the measured bandwidths to the variable control unit 120 and the scheduler 140.

The variable control unit 120 may calculate a packet distribution vector \vec{n}ₚₖₜ for determining the unit or size of data distributed into the server and the peers and a fountain coding rate c(\vec{n}ₚₖₜ) for determining an encoding applied on data to be stored in the server and peers based on the information on measured bandwidths and transmission times calculated by the scheduler 140.

Here, the packet distribution vector may be represented as \vec{n}ₚₖₜ=(n_{cs}^{pkt}, n₁^{pkt}, n₂^{pkt}, . . . , n_{|U}_{_{initial—set}}_{|}^{pkt}), and the first element n_{cs}^{pkt} and other elements nᵢ^{pkt} of the packet distribution vector may represent the number of packets including encoded symbols to be distributed into the server and peers. Also, Uᵢₙᵢₜᵢₐₗ_{_}ₛₑₜ may represent, as an initial set of peers provided to the user, the number of peers in which data can be stored.

The encoding unit 130 may perform a fountain encoding on data to be stored in the server and peers according to the fountain encoding rate determined by the variable control unit 120. For example, the encoding unit 130 may use Luby Transform (LT) codes or Raptor codes. Especially, the encoding unit 130 may perform LT encoding.

The scheduler 140 may calculate transmission times required for transmitting data to the server and peers based on the measured bandwidths and the packet distribution vector, and transfer information on the calculated transmission times to the variable control unit 120. Accordingly, the variable control unit 120 may recalculate the packet distribution vector by using the information on the measured bandwidths and transmission times.

Also, the scheduler 140 may transmit symbols encoded based on the fountain coding rate to the server and the peers according to the packet distribution vector.

The encoded symbols generated by the encoding unit 130 may be transmitted to the server and the peers according to the packet distributing vector.

In the below description, terminologies used in the present specification will be explained in order to explain functions of the hybrid storage system 100 according to an exemplary embodiment of the present disclosure.

‘Node availability’ may mean a probability that data stored in a server of the cloud storage system or a peer in the P2P storage system can be retrieved during a predetermined time. Here, a ‘node’ may mean a server in the cloud storage or a peer in the P2P storage.

The node availability may be calculated as follows. A live time of a peer in the P2P storage system may be dependent upon a time of its stay time in the storage system. Thus, the node availability of the peer may be calculated based on the following equation 1.

$${p}_{i} = P \{ X \geq {T}_{i}^{stay} + {T}_{req} \vert X \geq {T}_{i }^{stay} \} = \frac{P \{ X \geq {T}_{i}^{stay} + {T}_{req} \}}{P \{ X \geq {T}_{i}^{stay} \}} \qquad [ Equation 1 ]$$

In the equation 1, X may mean a time for which the peer will exist in the storage system. Accordingly, the node availability according to the equation 1 may mean a probability that the i-th peer staying in the storage system for Tᵢ^{stay} will exist in the storage system for not less than T_{req}. Here, the random variable X may be modeled using Pareto distribution.

Also, a ‘system reliability’ may mean a probability of obtaining encoded symbols as or more than required for successful fountain decoding.

The system reliability may be calculated as follows. The reliability of the hybrid storage system 100 may be calculated based on the node availability. In order to calculate the system reliability, two matrixes may be defined as represented in the below equations 2 and 5.

$$A = {( {\to }_{{a}_{1}} {\to }_{{a}_{2}} … {\to }_{{a}_{i}} … {}_{{a}_{{N}_{row}}} )}^{T} \qquad [ Equation 2 ]$$

The equation 2 may represent a node combination matrix.

The node combination matrix according to the equation 2 may have node state vectors

$$( {\vec{a}}_{i} )$$

at its elements.

The node state vector may be represented as shown in the following equation 3.

$$\begin{matrix}{\vec{a}}_{i} = ( {a}_{i , cs} , {a}_{i , 1} , {a}_{i , 2} , … , {a}_{i , j} , … , {a}_{i , \vert {U}_{initial\_set} \vert} ) & [ Equation 3 ] \\ {N}_{row} = 2 \cdot {\sum }_{q = 1}^{\vert {U}_{initial\_set} \vert} ( \begin{matrix}\vert {U}_{initial\_set} \vert \\ q\end{matrix} ) & [ Equation 4 ]\end{matrix}$$

Here, Uᵢₙᵢₜᵢₐₗ_{_}ₛₑₜ may mean an initial set of peers provided to the user.

According to the equation 2, a value of an element corresponding to a node state vector may be configured as ‘1’ if the server of the cloud storage or the peer of the P2P storage can be accessed during the given T_{req}. If not, the value of the element corresponding to the node state vector may be configured as ‘0’.

The equation 5 may represent an event probability matrix.

E=(\vec{e}₁ \vec{e}₂ . . . \vec{e}ᵢ . . . \vec{e}_{N}_{_{row}})^{T} [Equation 5]

In the equation 5, respective elements may be defined according to the following equations 6 to 8.

$$\begin{matrix}{\vec{e}}_{i} = ( {e}_{i , cs} ( {\vec{n}}_{pkt} ) {e}_{i , 1} ( {\vec{n}}_{pkt} ) , {e}_{i , 2} ( {\vec{n}}_{pkt} ) , … , {e}_{i , j} ( {\vec{n}}_{pkt} ) , … , {e}_{i , \vert {U}_{initial\_set} \vert} ( {\vec{n}}_{pkt} ) ) & [ Equation 6 ] \\ {e}_{i , cs} ( {\vec{n}}_{pkt} ) = \{ \begin{matrix}{p}_{cs} & if {N}_{ps} \cdot ( {\vec{a}}_{i} \cdot {\vec{n}}_{pkt} ) \geq {K}_{min} and {a}_{i , cs} = 1 \\ 1 - {p}_{cs} & if {N}_{ps} \cdot ( {\vec{a}}_{i} \cdot {\vec{n}}_{pkt} ) \geq {K}_{min} and {a}_{i , cs} = 0 \\ 0 & otherwise\end{matrix} & [ Equation 7 ] \\ {e}_{i , j} ( {\vec{n}}_{pkt} ) = \{ \begin{matrix}{p}_{j} & if {N}_{ps} \cdot ( {\vec{a}}_{i} \cdot {\vec{n}}_{pkt} ) \geq {K}_{min} and {a}_{i , j} = 1 \\ 1 - {p}_{j} & if {N}_{ps} \cdot ( {\vec{a}}_{i} \cdot {\vec{n}}_{pkt} ) \geq {K}_{min} and {a}_{i , j} = 0 \\ 0 & otherwise\end{matrix} & [ Equation 8 ]\end{matrix}$$

Respective elements in the equation 5 may represent probability values calculated based on the equation 7 and equation 8.

In the equations 7 and 8, ‘•’ may mean an inner product operator. A value obtained by multiplying all elements of \vec{e}ᵢ may be a probability of obtaining encoded symbols more than Kₘᵢₙ in case that the node state vector is \vec{a}ᵢ. Here, Nₚₛ is the number of encoded symbols included in a packet, and Kₘᵢₙ may mean the number of encoded symbols required for successfully decoding a source symbol.

Accordingly, the system reliability may be represented by using elements of the event probability matrix as shown in the below equation 9.

$$SR ( {\vec{n}}_{pkt} ) = {\sum }_{i = 1}^{{N}_{row}} ( {e}_{i , cs} ( {\vec{n}}_{pkt} ) \cdot {\prod }_{j = 1}^{\vert {U}_{initial\_set} \vert} {e}_{i , j} ( {\vec{n}}_{pkt} ) ) \qquad [ Equation 9 ]$$

At last, ‘data retrievability’ may mean a probability that a user can retrieve user data stored in the hybrid storage system 100 without errors.

The data retrievability may be calculated as follows. Even though a part of the encoded symbols generated by fountain encoding is lost, if encoded symbols more than a certain threshold are obtained, the source symbol can be retrieved with a determined probability. For example, a relation among a LT decoding failure rate (δ_{failure}), the number of source symbols (K_{source}), and the number of encoded symbols required for successfully decoding as many source symbols as K_{source} (Kₘᵢₙ) may be defined by the following equation 10.

$${K}_{min} = {K}_{source} + 2 \cdot ln ( \frac{ω \cdot ln ( \frac{{K}_{source}}{{δ}_{failure}} ) \cdot \sqrt{{K}_{source}}}{{δ}_{failure}} ) \cdot ω \cdot ln ( \frac{{K}_{source}}{{δ}_{failure}} ) \cdot \sqrt{{K}_{source}} \qquad [ Equation 10 ]$$

In the equation 10, ω may mean a variable according to a robust solution distribution, and may be a small real value.

According to the equation 10, the user may decode all source symbols with high success probability by using encoded symbols slightly more than the number of source symbols.

The data retrievability may be calculated by using the below equation 11.

DR(\vec{n}ₚₖₜ)=(1−δ_{failure})·SR(\vec{n}ₚₖₜ) [Equation 11]

That is, the equation 11 may represent a probability that the source symbols can be retrieved from the encoded symbols without errors.

According to the following equation 12, the variable control unit 120 in the hybrid storage system 100 according to an exemplary embodiment of the present disclosure may determine the packet distribution vector so that the data retrievability becomes above a predetermined threshold Pᵣₑₜᵣᵢₑᵥₑ^{min}. Here, Pᵣₑₜᵣᵢₑᵥₑ^{min} may mean a minimum data retrievability required by the storage system. That is, the variable control unit 120 may determine the packet distribution vector so as to make the data retrievability above the predetermined threshold.

Specifically, the data retrievability may be calculated based on the decoding failure rate and the system reliability, and the decoding failure rate may be calculated based on the number of source symbols and the number of encoded symbols required for successfully decoding the source symbols. Here, the system reliability may mean a probability of obtaining encoded symbols equal to or more than the number of encoded symbols required for decoding the source symbols.

DR(\vec{n}ₚₖₜ)≧Pᵣₑₜᵣᵢₑᵥₑ^{min} [Equation 12]

Also, the variable control unit 120 may determine the packet distribution part so that the transmission time

$${T}_{up} ( {\vec{n}}_{pkt} , \vec{bw} )$$

can be minimized.

Furthermore, the variable control unit 120 may guarantee the user's data privacy by storing encoded symbols equal to or less than the number of source symbols in the cloud storage server and P2P storage peers so as to satisfy the following equation 13.

$${n}_{cs}^{pkt} < ⌈ \frac{{K}_{source}}{{N}_{ps}} ⌉ \\ and \\ {n}_{l}^{pkt} < min \{ ⌈ \frac{{h}_{l}}{{S}_{symbol} \cdot {N}_{ps}} ⌉ , ⌈ \frac{{K}_{source}}{{N}_{ps}} ⌉ \} , \\ for \\ 1 \leq l \leq \vert {U}_{initial\_set} \vert \qquad [ Equation 13 ]$$

In the equation 13, hᵢ may mean a storage space remaining in the i-th peer, S_{symbol} may mean a symbol size, and Nₚₛ may mean the number of encoded symbols included in a packet.

Referring to the equation 13, the variable control unit 120 may determine the packet distribution vector so that encoded symbols less than the source symbols in the cloud storage server and P2P peers based on the storage space remaining to the peers and the number of encoded symbols included in a packet.

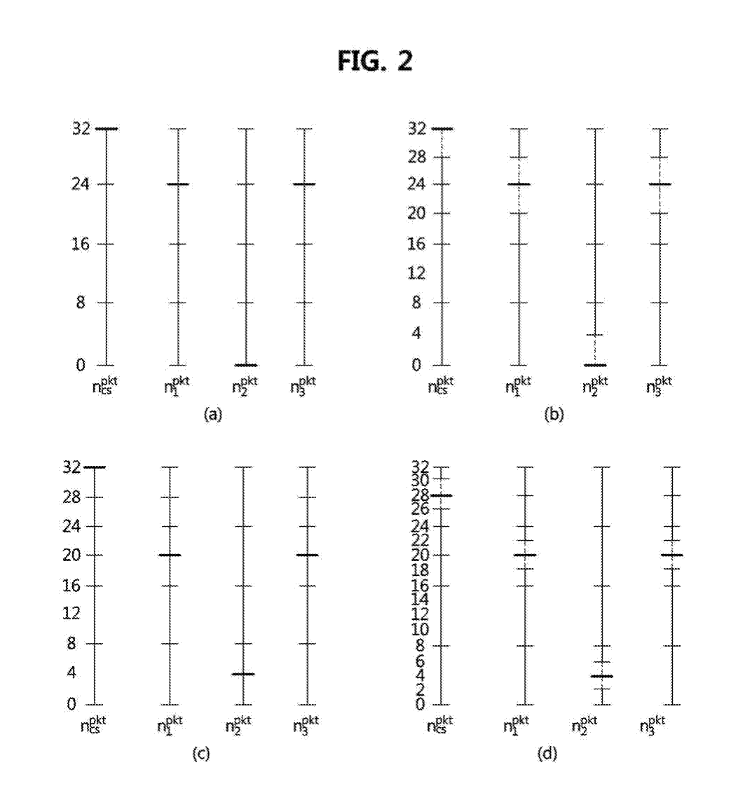

FIG. 2 is a conceptual diagram explaining determination of a packet distribution vector according to an exemplary embodiment of the present disclosure.

Referring to FIG. 2, the size of packet transmitted to the cloud storage server or P2P peers may be determined through determination and re-determination of the packet distribution vector. For example, FIG. 2 illustrates the size of packets transmitted to respective nodes in case that four nodes are selected. Here, the size of packet may determine the size of a source block.

Specifically, the determination and re-determination of the packet distribution vector may be a procedure of narrowing an interval of the number of packets and search range of packets to be stored in respective nodes.

FIG. 2 illustrates a procedure of determining the packet distribution vector representing the number of packets transmitted to respective nodes in case that a single cloud storage server and three peers are provided to a user.

In FIG. 2, the maximum number of packets which can be stored in (or, can be transmitted to) each node may be assumed to be 32.

A procedure (a) of FIG. 2 illustrates a procedure of setting an initial interval for determining the packet distribution vector (for example, the initial interval is set to 8 in (a) of FIG. 2.)

In a procedure (b) of FIG. 2, a temporary packet distribution vector may be determined based on the initial interval set in the procedure (a) of FIG. 2, and the search interval (e.g., to 4) and a search range may be narrowed by one step.

In a procedure (c) of FIG. 2, the temporary packet distribution vector may be re-determined based on the 1 step-narrowed search interval and search range. Also, in a procedure (d) of FIG. 2, the search interval (e.g., to 2) and search range may be further narrowed down by 1 more step based on the temporary packet distribution vector determined in the procedure (c) of FIG. 2.

Such the procedures are repeated until the search interval reaches 1. Thus, referring to FIG. 2, the size of packets transmitted to the cloud storage server or P2P storage peers may be determined through the determination and re-determination of the packet distribution vector.

An algorithm for determining control variables such as the packet distribution vector may comprise the following two procedures.

The first procedure is determining the packet distribution vector within a given peer set with low complexity, and the second procedure is re-determining the packet distribution vector properly according to time-varying bandwidth during transmission.

First, a detail procedure for storing a first source block of a file (data) in the hybrid storage system 100 according to an exemplary embodiment of the present disclosure may be performed as follows.

<First Step>

The number of packet-intervals Nᵢₙₜ may be set to 2^{m}. Here, m may be an integer value between 0 and

$$⌊ {log}_{2} \frac{{K}_{source}}{{N}_{ps}} ⌋ .$$

For all i (0≦i≦|Uᵢₙᵢₜᵢₐₗ_{_}ₛₑₜ|), nᵢⁿⁱⁿ may be initialized to 0, nᵢ^{max} may be initialized to

$$⌊ {log}_{2} \frac{{K}_{source}}{{N}_{ps}} ⌋ ,$$

and Nᵢ^{int} may be initialized to Nᵢₙₜ.

Then, according to the below equation 14, the intervals of the rest of packets may be determined.

$${n}_{i}^{pkt} ( k ) = {n}_{i}^{min} + k \cdot \frac{{n}_{i}^{max} - {n}_{i}^{min}}{{N}_{i}^{int}} \qquad [ Equation 14 ]$$

In the equation 14, nᵢ^{pkt}(k) may represent the number of packets to be transmitted to the i-th peer, and n₀^{pkt}(k) may represent the number of packets which are exceptionally allocated to the cloud storage server.

<Second Step>

\vec{n}ₚₖₜ^{cur}=(n₀^{cur}, n₁^{cur}, . . . , nᵢ^{cur}, . . . , n_{|U}_{_{initial—set}}_{|}^{cur}) may be assumed as the optimal packet distribution vector minimizing the transmission time obtained in the first step. The minimum point nᵢ^{min} and the maximum point nᵢ^{max} may be respectively updated based on

$$max \{ 0 , {n}_{i}^{cur} - \frac{{n}_{i}^{max} - {n}_{i}^{min}}{2 \cdot {N}_{i}^{int}} \}$$

$$and$$

$$min \{ {n}_{i}^{car} + \frac{{n}_{i}^{max} - {n}_{i}^{min}}{2 \cdot {N}_{i}^{int }} , {2}^{⌊ {log}_{2} \frac{{K}_{source}}{{N}_{ps}} ⌋} \} .$$

If nᵢ^{cur} is 0 or

$$2 ⌊ {log}_{2} \frac{{K}_{source}}{{N}_{ps}} ⌋ ,$$

Nᵢ^{int} may be set to 1. If not, Nᵢ^{int} may be set to 2.

<Third Step>

pkt , pkt

Until nᵢ^{pkt}(k)−nᵢ^{pkt}(k−1) becomes 1, the first step and the second step may be repeated.

(a) of FIG. 2 illustrates a case in which the first and second steps are repeated until k becomes 1, (b) and (c) of FIG. 2 illustrate cases in which the first and second steps are repeated until k becomes 2, and (d) of FIG. 2 illustrate a case in which the first and second steps are repeated until k becomes 3.

<Fourth Step>

Finally, a current packet distributing vector

$${\vec{n}}_{pkt}^{cur}$$

may be determined in order to transmit the first source block, and the fountain coding rate may be determined according to the below equation 15.

$$c ( {\vec{n}}_{pkt}^{cur} ) = \frac{{K}_{source}}{{N}_{ps} \cdot ( {\sum }_{i = 0}^{\vert {U}_{initial\_set} \vert} {n}_{i}^{cur} )} \qquad [ Equation 15 ]$$

Then, in order to cope with time-varying network environments during transmission, the rest of source blocks except the first source block may be transmitted as follows.

<First Step>

The bandwidth vector available for transmitting the rest of source blocks,

$$\vec{bw} = ( {bw}_{cs} , {bw}_{1} , … , {bw}_{i} , … , {bw}_{\vert {U}_{initial\_set} \vert} )$$

may be measured.

<Second Step>

It may be identified whether a change occurs in the bandwidth. If the bandwidth decreases between the user and the server or the peer, a peer included in an additional peer set U_{add} may be added to the initial peer set Uᵢₙᵢₜᵢₐₗ_{_}ₛₑₜ until a total sum of bandwidth of added peers is larger than the decreased amount of the bandwidth.

<Third Step>

The re-determination of the packet distribution vector based on the peers added to the initial peer set and the peers representing decrease of bandwidth may be performed.

<Fourth Step>

Until transmissions of all blocks are completed, the first to third steps may be performed repeatedly.

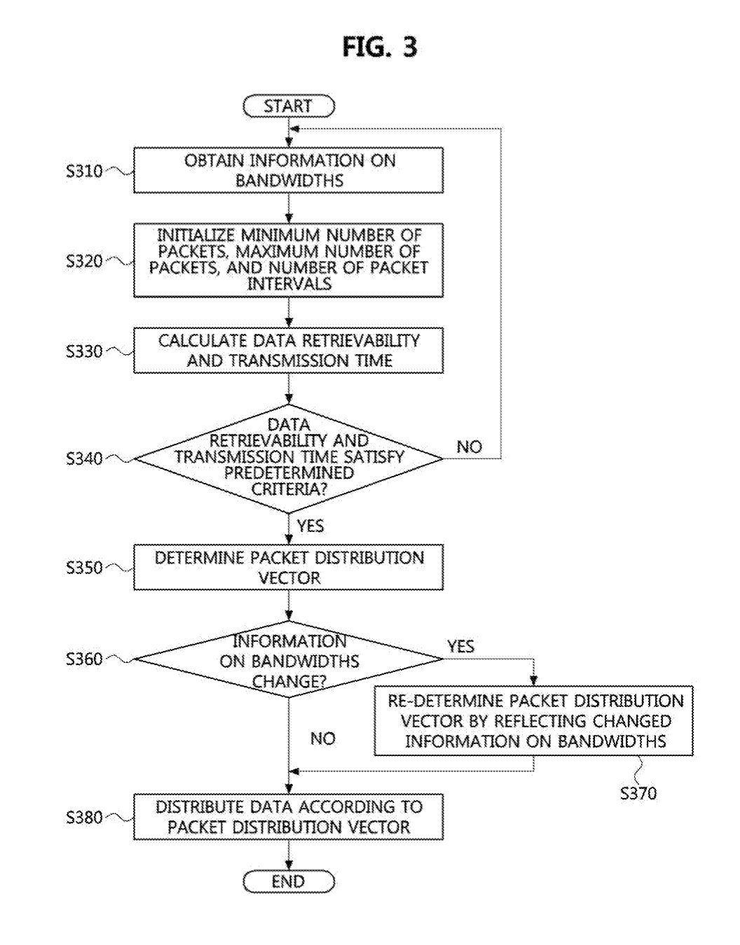

FIG. 3 is a flow chart explaining a data transmission method using a hybrid storage system according to an exemplary embodiment of the present disclosure.

Referring to FIG. 3, a procedure of transmitting or uploading data to a cloud storage server and a P2P storage peer through a hybrid storage system 100 will be explained. That is, a data transmission method using the hybrid storage system 100 according to an exemplary embodiment of the present disclosure may be performed through the above-described determination and re-determination of a packet distribution vector.

According to an exemplary embodiment of the present disclosure, using the hybrid storage system 100, data may be transmitted or uploaded to the cloud storage server and the P2P storage peer in distributive manner.

First, information on bandwidths of the server and the peers may be obtained (S310).

In order to determine a packet distribution vector based on the information on bandwidths, the minimum number of packets nᵢ^{min}, the maximum number of packets nᵢ^{max}, and the number of packet-intervals Nᵢₙₜ may be initialized (S320).

The data retrievability and the transmission times required for transmitting the data to the server and the peers may be calculated based on the information on bandwidths (S330).

Specifically, the data retrievability may be calculated based on a decoding failure rate and a system reliability, and the decoding failure rate may be calculated based on the number of encoded symbols required for decoding source symbols and the number of the source symbols. Here, the system reliability may mean a probability of obtaining symbols not less than the number of encoded symbols required for decoding the source symbols.

It may be determined whether the data retrievability and the transmission time satisfy predetermined thresholds (S340). In case that the data retrievability and the transmission time satisfy the predetermined thresholds, the corresponding packet distribution vector may be determined (S350). On the contrary, in case that the data retrievability and the transmission time do not satisfy the predetermined thresholds, the steps from the step S310 will be performed again.

Also, it may be identified whether the information on the bandwidths change or not (S360). If the information on the bandwidths are changed, the packet distribution vector may be re-determined by reflecting the changed information (S370). Here, the re-determination may be performed for transmission of the rest of source blocks except the first source block. For example, in case that bandwidths of the server and the peer decrease, peers may be added so that a sum of bandwidths of added peers becomes larger than the decreased amount of the bandwidths, and the packet distribution vector may be re-determined in consideration of the added peers.

Finally, the data may be transmitted to the server and the peers in distributive manner according to the determined packet distribution vector (S380). Also, the data may be transmitted as encoded according to a fountain coding rate determined based on the packet distribution vector. Here, the procedure of transmitting the data to the server and peers in distribute manner according to the packet distribution vector may be performed repeatedly until transmissions of all the source blocks are completed.

Furthermore, a procedure of downloading encoded symbols for the user to retrieve his data may be performed as follows.

In case that the user wants to retrieve his data, the user may request downloading of encoded symbols stored in the server or peers based on information on the peers storing the encoded symbols. In this case, the encoded symbols may be downloaded simultaneously downloaded from the server and a plurality of peers. If as many encoded symbols as required for decoding are downloaded, the downloading of the encoded symbols for the corresponding block may be finished, and downloading of encoded symbols for the next block may be started. Accordingly, the data may be obtained by downloading and decoding all encoded symbols.

According to exemplary embodiments of the present disclosure, in a hybrid storage system into which a cloud storage system and a P2P storage system are combined, data can be stored using minimum transmission time, data privacy problem being resolved, and data retrievability being enhanced.

While the example embodiments of the present invention and their advantages have been described in detail, it should be understood that various changes, substitutions and alterations may be made herein without departing from the scope of the invention.

1. A hybrid storage system comprising:
a node management unit measuring bandwidths for a cloud storage server and a Peer-to-Peer (P2P) storage peer;
a variable control unit calculating a packet distribution vector for determining data units to be distributed into the cloud storage server and the P2P storage peer, and a fountain coding rate for determining coding rates of data to be stored in the cloud storage server and the P2P storage peer;
an encoding unit performing encoding on the data to be stored in the cloud storage server and the P2P storage peer based on the fountain coding rate; and
a scheduler calculating a transmission time required to transmit data to the cloud storage server and the P2P storage peer based on the measured bandwidths and the packet distribution vector, and transferring information on the transmission time to the variable control unit.

2. The hybrid storage system according to claim 1, wherein the packet distribution vector represents a number of packets including encoded symbols distributed to the cloud storage server and a number of packets including encoded symbols distributed to the P2P storage peer.

3. The hybrid storage system according to claim 1, wherein the variable control unit re-calculates the packet distribution vector by using the measured bandwidths and the information on the transmission time.

4. The hybrid storage system according to claim 1, wherein the variable control unit determines the packet distribution vector so that data retrievability becomes not less than a predetermined threshold.

5. The hybrid storage system according to claim 4, wherein the data retrievability is calculated based on a decoding failure rate and a system reliability, the decoding failure rate is calculated based on a number of source symbols and a number of encoded symbols required for decoding the source symbols, and the system reliability is a probability of obtaining encoded symbols not less than the number of encoded symbols required for decoding the source symbols.

6. The hybrid storage system according to claim 1, wherein the variable control unit determines the packet distribution vector based on a storage space remaining in the peer and a number of encoded symbols included in a packet, so that encoded symbols less than a number of source symbols are stored in the server and the peer.

7. The hybrid storage system according to claim 1, wherein the encoding unit performs Luby Transform (LT) encoding.

8. The hybrid storage system according to claim 1, wherein the scheduler transmits symbols encoded according to the fountain coding rate to the cloud storage server and the P2P peer based on the packet distribution vector.

9. A method of distributing data into a cloud storage server and a Peer-to-Peer (P2P) storage server by using a hybrid storage system, the method comprising:
obtaining information on bandwidths for a cloud storage server and a Peer-to-Peer (P2P) storage peer;
initializing a minimum number of packets, a maximum number of packets, and a number of packet-intervals in order to determine a packet distribution vector based on the information on the bandwidths;
calculating a data retrievability rate and a transmission time required to transmit data to the cloud storage server and the P2P storage peer based on the information on the bandwidths; and
determining the packet distribution vector so that the data retrievability rate and the transmission time satisfy predetermined thresholds.

10. The method according to claim 9, further comprising transmitting data to the cloud storage server and the P2P storage peer in distributive manner according to the packet distribution vector.

11. The method according to claim 10, wherein, in the transmitting data to the cloud storage server and the P2P storage peer in distributive manner, the data are transmitted as encoded according to a fountain coding rate determined based on the packet distribution vector.

12. The method according to claim 9, wherein the data retrievability is calculated based on a decoding failure rate and a system reliability, the decoding failure rate is calculated based on a number of source symbols and a number of encoded symbols required for decoding the source symbols, and the system reliability is a probability of obtaining encoded symbols not less than the number of encoded symbols required for decoding the source symbols.

13. The method according to claim 9, wherein the determining the packet distribution vector further comprises re-determining the packet distribution vector by reflecting information on changed bandwidths when the bandwidths are changed.

14. The method according to claim 13, wherein, in the determining the packet distribution vector, when the bandwidths for the cloud storage server and the P2P storage peer decrease, a peer is added so that a bandwidth of the added peer is larger than a decreased amount of the bandwidths, and the packet distribution vector is re-determined according to the added peer.

15. An operation method performed by a hybrid storage system, comprising:
measuring bandwidths for a cloud storage server and a Peer-to-Peer (P2P) storage peer;
calculating a packet distribution vector for determining data units distributed into the cloud storage server and the P2P storage peer, and a fountain coding rate for determining encoding rates of data to be stored in the cloud storage server and the P2P storage peer;
encoding the data to be stored in the cloud storage server and the P2P storage peer based on the fountain coding rate; and
calculating a transmission time required to transmit data to the cloud storage server and the P2P storage peer based on the measured bandwidths and the packet distribution vector, and transferring information on the transmission time to the variable control unit.

16. The method according to claim 15, further comprising re-calculating the packet distribution vector by using the measured bandwidths and the information on the transmission time.

17. The method according to claim 15, further comprising transmitting data to the cloud storage server and the P2P storage peer in distributive manner according to the packet distribution vector.
